(19) United States
(12) Patent Application Publication
(10) Pub. No.: US 2025/0005243 A1
(43) Pub. Date: Jan. 2, 2025

(54) INTEGRATED CIRCUIT DESIGN VERIFICATION WITH SIGNAL FORCING

(71) Applicant: SiFive, Inc., Santa Clara, CA (US)

(72) Inventors: Adam Moshe Izraelevitz, San Mateo, CA (US); Albert Pengju Chen, San Mateo, CA (US)

(73) Assignee: SiFive, Inc., Santa Clara, CA (US)

(21) Appl. No.: 18/805,414

(22) Filed: Aug. 14, 2024

Related U.S. Application Data
(63) Continuation of application No. PCT/US2023/010587, filed on Jan. 11, 2023.
(60) Provisional application No. 63/311,546, filed on Feb. 18, 2022.

(51) Int. Cl. G06F 30/3308

(52) U.S. Cl. CPC G06F 30/3308

(57) ABSTRACT

An integrated circuit design may be generated for an integrated circuit. The integrated circuit design may include an instance of a module description that describes a functional operation of a module. The instance may include an input that is internal to the integrated circuit design. The integrated circuit design may be encoded in an intermediate representation (IR) data structure. A parameter may be received indicating that the input should be exposed to a simulator. The IR data structure may be compiled to produce a register-transfer level (RTL) data structure. The RTL data structure may encode a logic description associated with the instance. The parameter may be used to permit a simulator to access a node in the RTL data structure that is associated with the input.

### CROSS-REFERENCES TO RELATED APPLICATIONS

This application is a continuation of International Application No. PCT/US2023/010587, filed Jan. 11, 2023, which claims priority to U.S. Provisional Application No. 63/311,546, filed Feb. 18, 2022, the entire contents of which are incorporated herein by reference for all purposes.

### FIELD OF TECHNOLOGY

This disclosure relates generally to integrated circuit design and, more specifically, to integrated circuit design verification with signal forcing.

### BACKGROUND

Integrated circuits may be designed and tested in a multi-step process that involves multiple specialized engineers performing a variety of different design and verification tasks on an integrated circuit design. A variety of integrated circuit design tool chains may be used by these engineers to handle different parts of the integrated circuit design workflow of using commercial electronic design automation (EDA) tools.

### BRIEF DESCRIPTION OF THE DRAWINGS

The disclosure is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity.

FIG. 1 is a block diagram of an example of a system for facilitating generation and manufacture of integrated circuits.

FIG. 2 is a block diagram of an example of a system for facilitating generation of integrated circuits.

FIG. 3 is a block diagram of an example of a system for integrated circuit design verification with signal forcing.

FIG. 4 is a block diagram of another example of a system for integrated circuit design verification with signal forcing.

FIG. 5 is a block diagram of an example of a system including an integrated circuit design with instances of module descriptions.

FIG. 6 is a block diagram of an example of a system including an integrated circuit design in which an input of an instance of a module description is selected for signal forcing.

FIG. 7 is flow chart of a process for integrated circuit design verification with signal forcing.

FIG. 8 is flow chart of another process for integrated circuit design verification with signal forcing.

### DETAILED DESCRIPTION

Automated generation of integrated circuit designs permits a configuration of an application specific integrated circuit (ASIC) or a system on a chip (SoC) to be specified in terms of design parameters (or colloquially knobs). A system may then automate the operation of commercial electronic design automation (EDA) tools for design of the integrated circuit using the design parameters.

For example, a system may execute an integrated circuit generator (or simply a generator) to access design parameters and generate an integrated circuit design. In some implementations, the generator may use a hardware description language (HDL) embedded in a general-purpose programming language (e.g., Scala) that supports object-oriented programming and/or functional programming. For example, Chisel, an open source HDL embedded in Scala, a statically typed general purpose programming language that supports both object-oriented programming and functional programming, may be used to generate an integrated circuit design. The generator may include module descriptions that specify input(s), output(s), and/or a description(s) of a functional operation of a module (e.g., a processor core, cache, or the like, which may be represented, for example, by a Scala class).

In a process referred to as elaboration, the generator may execute to generate an integrated circuit design based on the design parameters. The integrated circuit design may include instances of module descriptions with connections being made. For example, the generator may execute constructor code to establish instances of Scala classes, with wired connections between them, as an instantiation of an integrated circuit design. In some implementations, the integrated circuit design may be encoded in an intermediate representation (IR) data structure. The IR data structure may be configured for optimization and/or translation by a compiler to produce a register-transfer level (RTL) data structure. For example, the generator may generate the integrated circuit design as a flexible intermediate representation for register-transfer level (FIRRTL) data structure. The FIRRTL data structure may be compiled by a FIRRTL compiler to produce an RTL data structure.

In a process referred to as compilation, the elaborated integrated circuit design (e.g., the IR data structure) may be compiled to generate an RTL data structure. For example, compiling the integrated circuit design may comprise executing one or more lowering transformations (e.g., compiler transformations that remove high-level constructs) to transform the integrated circuit design to generate the RTL data structure. The RTL data structure may encode a topology of logic associated with the instances of module descriptions implemented in the integrated circuit design (e.g., logic descriptions of the modules, such as the processor cores, caches, and the like). The RTL data structure may be compatible with EDA tools that may be used for functional verification (e.g., simulation analysis), synthesis (e.g., conversion to a gate-level description), placement and routing (e.g., physical design), and/or manufacturing of an integrated circuit (e.g., a processor, a microcontroller, an ASIC, or an SoC). In some implementations, the RTL data structure may comprise Verilog. For example, the integrated circuit design may be compiled using a FIRRTL compiler to generate Verilog.

During the design process, it may be useful to verify (e.g., test) the logic descriptions associated with one or more modules implemented in the RTL data structure, such as one of the processor cores or caches. One technique for testing such logic descriptions is to permit a simulator to write and/or read signal values on one or more nodes associated with a module. Writing a signal value to a node may comprise injecting a signal value or logic (e.g., signal forcing) on a node that is associated with an input to the module, such as injecting a logic high (“1”) or a logic low (“0”) value. Reading a signal value from a node may comprise detecting a signal value or logic (e.g., signal monitoring) on a node that is associated with an output of the module, such as detecting a logic high (“1”) or a logic low (“0”) value. This may permit changing states and/or reading states associated with the module. For example, to verify a logic description associated with a cache that implements error correction code (ECC) logic, it may be desirable for a simulator to inject a signal value on a node associated with an input to the cache. The simulator might inject the signal value to induce an ECC error in the cache (e.g., flip a bit). The simulator may then monitor a signal value on a node associated with an output of the cache to determine whether the cache properly detected the error and/or corrected the error.

While a simulator may access nodes that are external to a design (e.g., system level inputs and/or outputs of the RTL data structure), providing the simulator with access to nodes that are internal to the design may be a manual and/or time consuming process. For example, providing access to nodes that are internal to the design may involve manually editing the RTL data structure in multiple locations to include cross module references, force statements, and/or binding logic (and/or preparing such cross module references, force statements, and/or binding logic in a separate configuration file). Further, when a change is made by the integrated circuit generator, the RTL data structure may become out of sync with the integrated circuit design that is produced by the generator. As a result, the integrated circuit design may be compiled again, which may involve manually editing the RTL data structure again. Accordingly, there is a need to permit testing of logic descriptions in an RTL data structure in a way that improves efficiency and/or keeps the design and simulation processes in sync.

Described herein are techniques which permit testing of logic descriptions in an RTL data structure (e.g., simulation). An integrated circuit generator may be used to generate an integrated circuit design including instances of module descriptions. A module description may specify input(s), output(s), and/or a description(s) of a functional operation of a module (e.g., a processor core, cache, or the like, which may be represented, for example, by a Scala class). Instances of module descriptions may include input(s) and/or output(s) (e.g., wires) that may be internal to the integrated circuit design (e.g., as opposed to a system level input(s) and/or output(s) that may be external to the integrated circuit design). The generator (e.g., Chisel) may use an HDL embedded in a general-purpose programming language (e.g., Scala) to generate the integrated circuit design. The integrated circuit design may be encoded in an IR data structure. A control interface, such as an application program interface (API), may receive a parameter indicating that an input of an instance of a module description should be exposed to a simulator. A compiler (e.g., a FIRRTL compiler) may compile the IR data structure to produce an RTL data structure. The RTL data structure may encode logic descriptions associated with the instances of module descriptions implemented in the integrated circuit design (e.g., Verilog). The parameter may be used to permit a simulator to access a node associated with the input (e.g., to force a signal value to the node) in the RTL data structure.

In some implementations, the control interface may receive a parameter indicating that an output of an instance of a module description should be exposed to a simulator. The parameter may be used to permit a simulator to access a node associated with the output (e.g., to monitor a signal value at the node) in the RTL data structure. In some implementations, a point in the integrated circuit design may be an input and an output (e.g., bi-directional or “I/O”), and the parameter may be used to permit a simulator to access the node associated with the input and the output (e.g., to force a signal value and/or to monitor a signal value at the node) in the RTL data structure.

In some implementations, the parameter may be used to generate an annotation for a compiler that is used to compile the integrated circuit design to generate an RTL data structure. For example, the parameter may be used to generate an annotation for a FIRRTL compiler that is used to compile the integrated circuit design to generate Verilog. The annotation may be used to build and/or modify one or more transformations that are used by the compiler. For example, the compiler may use the annotation to configure cross module references, force statements, and/or binding logic (e.g., Verilog forces) to permit access to the one or more nodes by the simulator.

In some implementations, the parameter may be used to generate a configuration file (e.g., instructions) that specifies the node. The configuration file may permit the simulator to force the signal value to the node, and/or monitor a signal value at the node, when simulating the RTL data structure. For example, a simulator that natively supports force statements (e.g., Synopsys VCS®) may use the configuration file to force a signal value to the node, and/or monitor a signal value at the node, when simulating the RTL data structure.

In some implementations, the parameter may be used to configure the RTL data structure to permit the simulator to force the signal value to the node and/or monitor a signal value at the node (e.g., without generating a configuration file). For example, a simulator that does not natively support force statements (e.g., Verilator) may use the RTL data structure, as configured by the compiler, to force a signal value to the node, and/or monitor a signal value at the node, when simulating the RTL data structure. As a result, techniques described herein may permit testing of logic in an RTL data structure in a way that improves efficiency and/or keeps the design and simulation processes in sync.

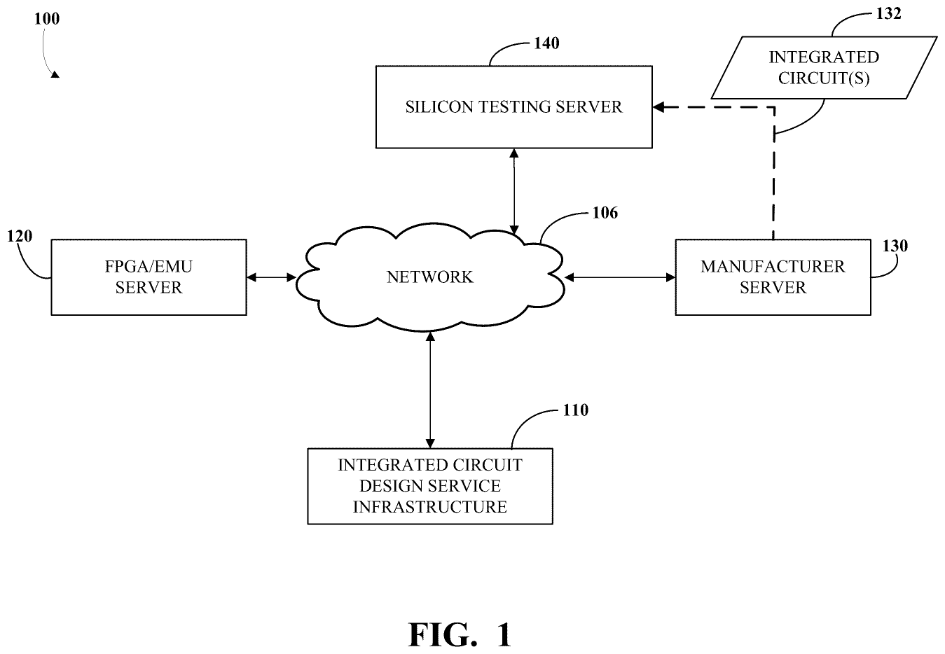

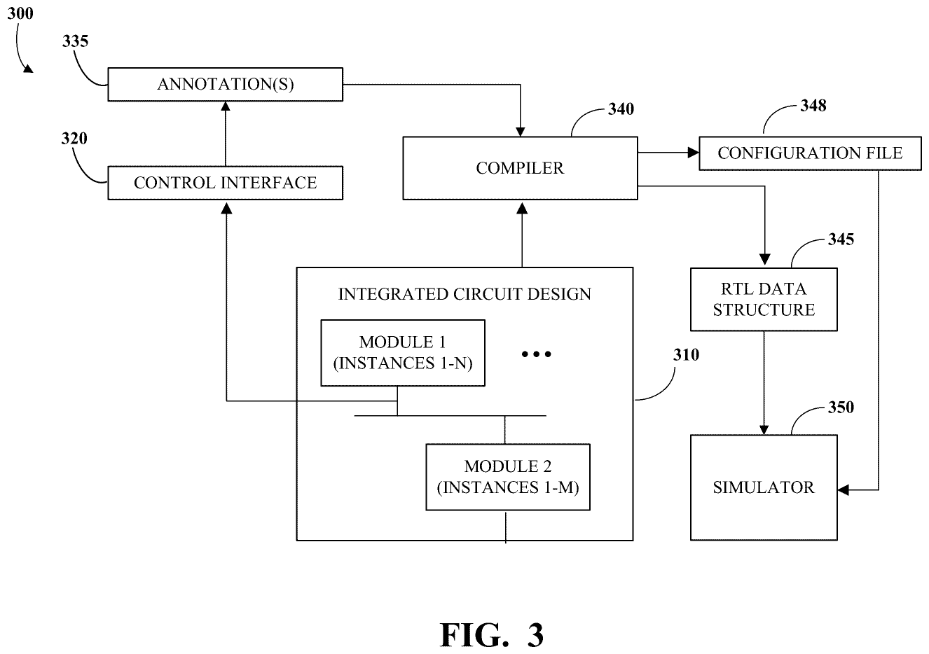

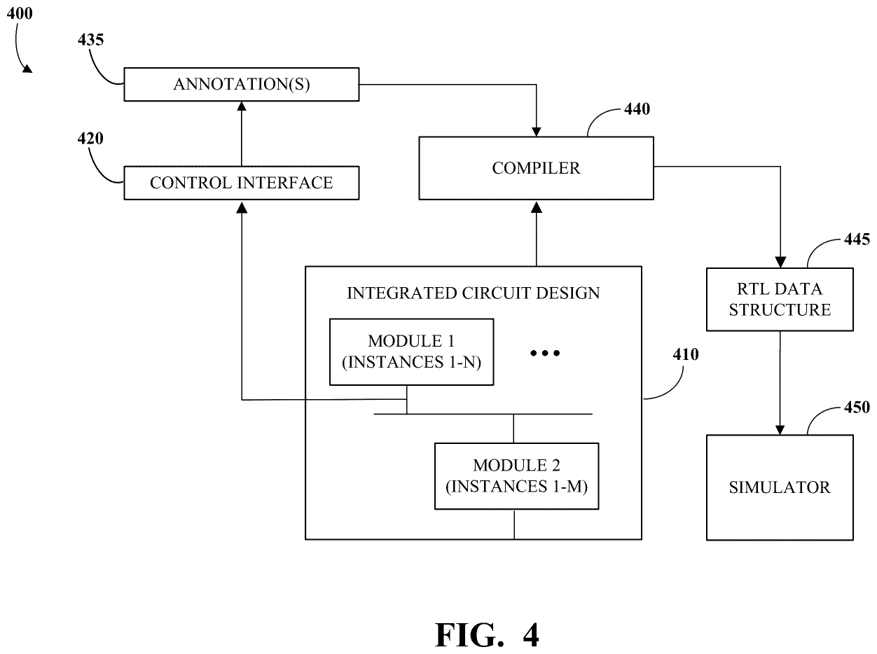

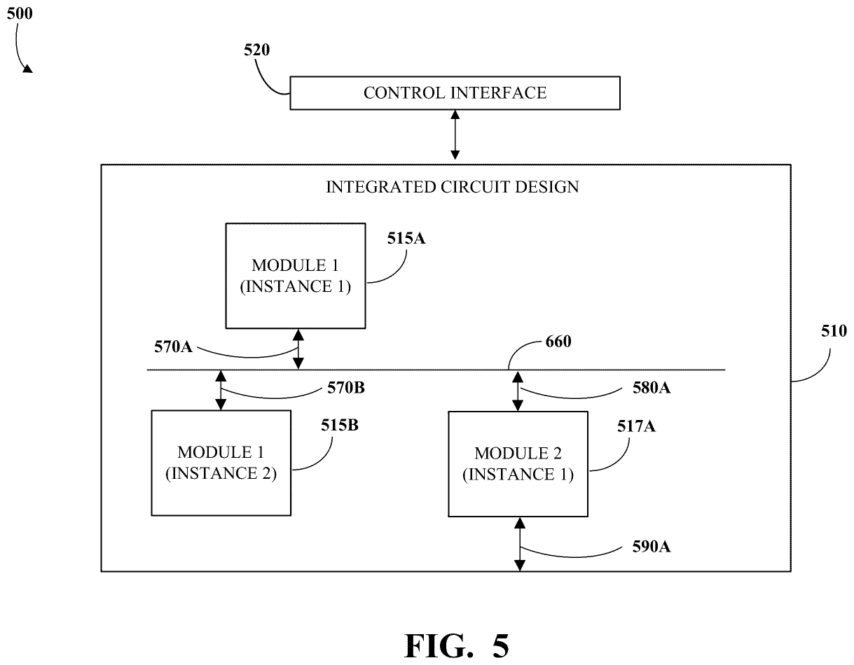

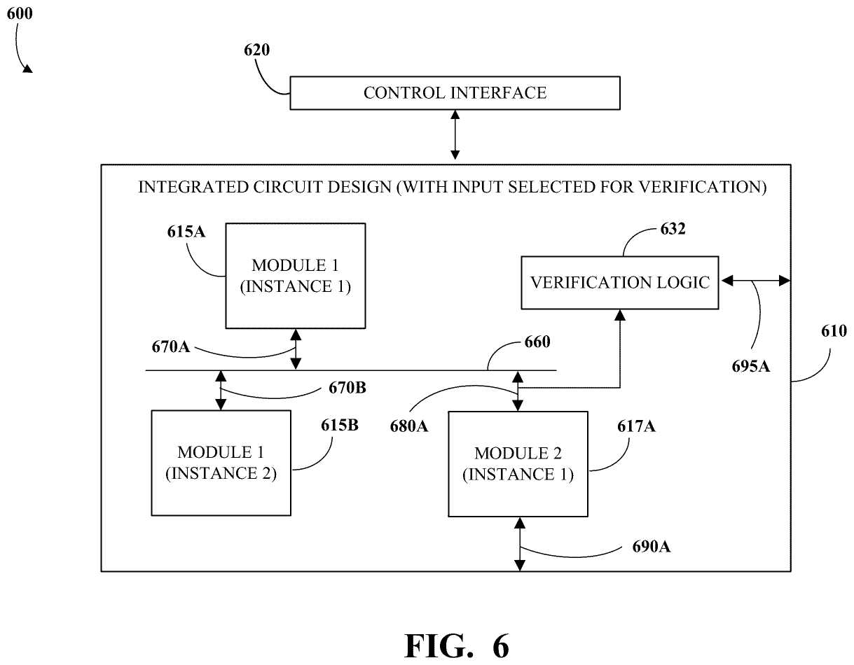

FIG. 1 is a block diagram of an example of a system 100 for generation and manufacture of integrated circuits. The system 100 includes a network 106, an integrated circuit design service infrastructure 110 (e.g., integrated circuit generator), a field programmable gate array (FPGA)/emulator server 120, and a manufacturer server 130. For example, a user may utilize a web client or a scripting application program interface (API) client to command the integrated circuit design service infrastructure 110 to automatically generate an integrated circuit design based on a set of design parameter values selected by the user for one or more template integrated circuit designs. In some implementations, the integrated circuit design service infrastructure 110 may be configured to generate an integrated circuit design like the integrated circuit design 310 shown in FIG. 3, the integrated circuit design 410 shown in FIG. 4, the integrated circuit design 510 shown in FIG. 5, and/or the integrated circuit design 610 shown in FIG. 6.

The integrated circuit design service infrastructure 110 may include a register-transfer level (RTL) service module configured to generate an RTL data structure for the integrated circuit based on a design parameters data structure. For example, the RTL service module may be implemented as Scala code. For example, the RTL service module may be implemented using Chisel. For example, the RTL service module may be implemented using flexible intermediate representation for register-transfer level (FIRRTL) and/or a FIRRTL compiler. For example, the RTL service module may be implemented using Diplomacy. For example, the RTL service module may enable a well-designed chip to be automatically developed from a high level set of configuration settings using a mix of Diplomacy, Chisel, and FIRRTL. The RTL service module may take the design parameters data structure (e.g., a java script object notation (JSON) file) as input and output an RTL data structure (e.g., a Verilog file) for the chip.

In some implementations, the integrated circuit design service infrastructure 110 may invoke (e.g., via network communications over the network 106) testing of the resulting design that is performed by the FPGA/emulation server 120 that is running one or more FPGAs or other types of hardware or software emulators. For example, the integrated circuit design service infrastructure 110 may invoke a test using a field programmable gate array, programmed based on a field programmable gate array emulation data structure, to obtain an emulation result. The field programmable gate array may be operating on the FPGA/emulation server 120, which may be a cloud server. Test results may be returned by the FPGA/emulation server 120 to the integrated circuit design service infrastructure 110 and relayed in a useful format to the user (e.g., via a web client or a scripting API client).

The integrated circuit design service infrastructure 110 may also facilitate the manufacture of integrated circuits using the integrated circuit design in a manufacturing facility associated with the manufacturer server 130. In some implementations, a physical design specification (e.g., a graphic data system (GDS) file, such as a GDSII file) based on a physical design data structure for the integrated circuit is transmitted to the manufacturer server 130 to invoke manufacturing of the integrated circuit (e.g., using manufacturing equipment of the associated manufacturer). For example, the manufacturer server 130 may host a foundry tape-out website that is configured to receive physical design specifications (e.g., such as a GDSII file or an open artwork system interchange standard (OASIS) file) to schedule or otherwise facilitate fabrication of integrated circuits. In some implementations, the integrated circuit design service infrastructure 110 supports multi-tenancy to allow multiple integrated circuit designs (e.g., from one or more users) to share fixed costs of manufacturing (e.g., reticle/mask generation, and/or shuttles wafer tests). For example, the integrated circuit design service infrastructure 110 may use a fixed package (e.g., a quasi-standardized packaging) that is defined to reduce fixed costs and facilitate sharing of reticle/mask, wafer test, and other fixed manufacturing costs. For example, the physical design specification may include one or more physical designs from one or more respective physical design data structures in order to facilitate multi-tenancy manufacturing.

In response to the transmission of the physical design specification, the manufacturer associated with the manufacturer server 130 may fabricate and/or test integrated circuits based on the integrated circuit design. For example, the associated manufacturer (e.g., a foundry) may perform optical proximity correction (OPC) and similar post-tape-out/pre-production processing, fabricate the integrated circuit(s) 132, update the integrated circuit design service infrastructure 110 (e.g., via communications with a controller or a web application server) periodically or asynchronously on the status of the manufacturing process, perform appropriate testing (e.g., wafer testing), and send to a packaging house for packaging. A packaging house may receive the finished wafers or dice from the manufacturer and test materials and update the integrated circuit design service infrastructure 110 on the status of the packaging and delivery process periodically or asynchronously. In some implementations, status updates may be relayed to the user when the user checks in using the web interface, and/or the controller might email the user that updates are available.

In some implementations, the resulting integrated circuit(s) 132 (e.g., physical chips) are delivered (e.g., via mail) to a silicon testing service provider associated with a silicon testing server 140. In some implementations, the resulting integrated circuit(s) 132 (e.g., physical chips) are installed in a system controlled by the silicon testing server 140 (e.g., a cloud server), making them quickly accessible to be run and tested remotely using network communications to control the operation of the integrated circuit(s) 132. For example, a login to the silicon testing server 140 controlling a manufactured integrated circuit(s) 132 may be sent to the integrated circuit design service infrastructure 110 and relayed to a user (e.g., via a web client). For example, the integrated circuit design service infrastructure 110 may be used to control testing of one or more integrated circuit(s) 132.

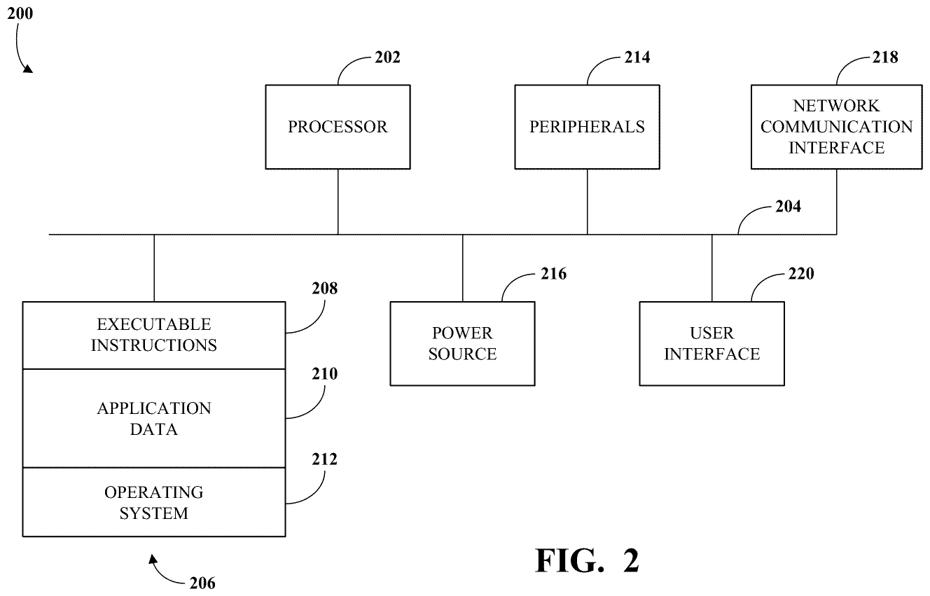

FIG. 2 is a block diagram of an example of a system 200 for facilitating generation of integrated circuits, for facilitating generation of a circuit representation for an integrated circuit, and/or for programming or manufacturing an integrated circuit. The system 200 is an example of an internal configuration of a computing device that may be used to implement the integrated circuit design service infrastructure 110, and/or to generate a file that generates a circuit representation of an integrated circuit design like the integrated circuit design 310 shown in FIG. 3, the integrated circuit design 410 shown in FIG. 4, the integrated circuit design 510 shown in FIG. 5, and/or the integrated circuit design 610 shown in FIG. 6. The system 200 can include components or units, such as a processor 202, a bus 204, a memory 206, peripherals 214, a power source 216, a network communication interface 218, a user interface 220, other suitable components, or a combination thereof.

The processor 202 can be a central processing unit (CPU), such as a microprocessor, and can include single or multiple processors having single or multiple processing cores. Alternatively, the processor 202 can include another type of device, or multiple devices, now existing or hereafter developed, capable of manipulating or processing information. For example, the processor 202 can include multiple processors interconnected in any manner, including hardwired or networked, including wirelessly networked. In some implementations, the operations of the processor 202 can be distributed across multiple physical devices or units that can be coupled directly or across a local area or other suitable type of network. In some implementations, the processor 202 can include a cache, or cache memory, for local storage of operating data or instructions.

The memory 206 can include volatile memory, non-volatile memory, or a combination thereof. For example, the memory 206 can include volatile memory, such as one or more dynamic random access memory (DRAM) modules such as double data rate (DDR) synchronous DRAM (SDRAM), and non-volatile memory, such as a disk drive, a solid-state drive, flash memory, Phase-Change Memory (PCM), or any form of non-volatile memory capable of persistent electronic information storage, such as in the absence of an active power supply. The memory 206 can include another type of device, or multiple devices, now existing or hereafter developed, capable of storing data or instructions for processing by the processor 202. The processor 202 can access or manipulate data in the memory 206 via the bus 204. Although shown as a single block in FIG. 2, the memory 206 can be implemented as multiple units. For example, a system 200 can include volatile memory, such as random access memory (RAM), and persistent memory, such as a hard drive or other storage.

The memory 206 can include executable instructions 208, data, such as application data 210, an operating system 212, or a combination thereof, for immediate access by the processor 202. The executable instructions 208 can include, for example, one or more application programs, which can be loaded or copied, in whole or in part, from non-volatile memory to volatile memory to be executed by the processor 202. The executable instructions 208 can be organized into programmable modules or algorithms, functional programs, codes, code segments, or combinations thereof to perform various functions described herein. For example, the executable instructions 208 can include instructions executable by the processor 202 to cause the system 200 to automatically, in response to a command, generate an integrated circuit design and associated test results based on a design parameters data structure. The application data 210 can include, for example, user files, database catalogs or dictionaries, configuration information or functional programs, such as a web browser, a web server, a database server, or a combination thereof. The operating system 212 can be, for example, Microsoft Windows®, macOS®, or Linux®; an operating system for a small device, such as a smartphone or tablet device; or an operating system for a large device, such as a mainframe computer. The memory 206 can comprise one or more devices and can utilize one or more types of storage, such as solid-state or magnetic storage.

The peripherals 214 can be coupled to the processor 202 via the bus 204. The peripherals 214 can be sensors or detectors, or devices containing any number of sensors or detectors, which can monitor the system 200 itself or the environment around the system 200. For example, a system 200 can contain a temperature sensor for measuring temperatures of components of the system 200, such as the processor 202. Other sensors or detectors can be used with the system 200, as can be contemplated. In some implementations, the power source 216 can be a battery, and the system 200 can operate independently of an external power distribution system. Any of the components of the system 200, such as the peripherals 214 or the power source 216, can communicate with the processor 202 via the bus 204.

The network communication interface 218 can also be coupled to the processor 202 via the bus 204. In some implementations, the network communication interface 218 can comprise one or more transceivers. The network communication interface 218 can, for example, provide a connection or link to a network, such as the network 106 shown in FIG. 1, via a network interface, which can be a wired network interface, such as Ethernet, or a wireless network interface. For example, the system 200 can communicate with other devices via the network communication interface 218 and the network interface using one or more network protocols, such as Ethernet, transmission control protocol (TCP), Internet protocol (IP), power line communication (PLC), Wi-Fi, infrared, general packet radio service (GPRS), global system for mobile communications (GSM), code division multiple access (CDMA), or other suitable protocols.

A user interface 220 can include a display; a positional input device, such as a mouse, touchpad, touchscreen, or the like; a keyboard; or other suitable human or machine interface devices. The user interface 220 can be coupled to the processor 202 via the bus 204. Other interface devices that permit a user to program or otherwise use the system 200 can be provided in addition to or as an alternative to a display. In some implementations, the user interface 220 can include a display, which can be a liquid crystal display (LCD), a cathode-ray tube (CRT), a light emitting diode (LED) display (e.g., an organic light emitting diode (OLED) display), or other suitable display. In some implementations, a client or server can omit the peripherals 214. The operations of the processor 202 can be distributed across multiple clients or servers, which can be coupled directly or across a local area or other suitable type of network. The memory 206 can be distributed across multiple clients or servers, such as network-based memory or memory in multiple clients or servers performing the operations of clients or servers. Although depicted here as a single bus, the bus 204 can be composed of multiple buses, which can be connected to one another through various bridges, controllers, or adapters.

A non-transitory computer readable medium may store a circuit representation that, when processed by a computer, is used to program or manufacture an integrated circuit. For example, the circuit representation may describe the integrated circuit specified using a computer readable syntax. The computer readable syntax may specify the structure or function of the integrated circuit or a combination thereof. In some implementations, the circuit representation may take the form of a hardware description language (HDL) program, a register-transfer level (RTL) data structure, a flexible intermediate representation for register-transfer level (FIRRTL) data structure, a Graphic Design System II (GDSII) data structure, a netlist, or a combination thereof. In some implementations, the integrated circuit may take the form of a field programmable gate array (FPGA), application specific integrated circuit (ASIC), system-on-a-chip (SoC), or some combination thereof. A computer may process the circuit representation in order to program or manufacture an integrated circuit, which may include programming a field programmable gate array (FPGA) or manufacturing an application specific integrated circuit (ASIC) or a system on a chip (SoC). In some implementations, the circuit representation may comprise a file that, when processed by a computer, may generate a new description of the integrated circuit. For example, the circuit representation could be written in a language such as Chisel, an HDL embedded in Scala, a statically typed general purpose programming language that supports both object-oriented programming and functional programming.

In an example, a circuit representation may be a Chisel language program which may be executed by the computer to produce a circuit representation expressed in a FIRRTL data structure. In some implementations, a design flow of processing steps may be utilized to process the circuit representation into one or more intermediate circuit representations followed by a final circuit representation which is then used to program or manufacture an integrated circuit. In one example, a circuit representation in the form of a Chisel program may be stored on a non-transitory computer readable medium and may be processed by a computer to produce a FIRRTL circuit representation. The FIRRTL circuit representation may be processed by a computer to produce an RTL circuit representation. The RTL circuit representation may be processed by the computer to produce a netlist circuit representation. The netlist circuit representation may be processed by the computer to produce a GDSII circuit representation. The GDSII circuit representation may be processed by the computer to produce the integrated circuit.

In another example, a circuit representation in the form of Verilog or VHDL may be stored on a non-transitory computer readable medium and may be processed by a computer to produce an RTL circuit representation. The RTL circuit representation may be processed by the computer to produce a netlist circuit representation. The netlist circuit representation may be processed by the computer to produce a GDSII circuit representation. The GDSII circuit representation may be processed by the computer to produce the integrated circuit. The foregoing steps may be executed by the same computer, different computers, or some combination thereof, depending on the implementation.

FIG. 3 is a block diagram of an example of a system 300 for integrated circuit design verification with signal forcing. The system 300 may include an integrated circuit design 310, a control interface 320, a compiler 340, and a simulator 350. An integrated circuit generator may be used to generate the integrated circuit design 310. For example, the integrated circuit design service infrastructure 110 shown in FIG. 1 may be used to generate the integrated circuit design 310. The generator may use an HDL embedded in a general-purpose programming language (e.g., Scala) that supports object-oriented programming and/or functional programming. For example, Chisel, an open source HDL embedded in Scala, a statically typed general purpose programming language that supports both object-oriented programming and functional programming, may be used to generate the integrated circuit design 310. The integrated circuit design 310 may be encoded in an IR data structure (e.g., a FIRRTL data structure).

The integrated circuit design 310 may include instances of module descriptions. A module description may describe a functional operation of a module (e.g., operation of a processor core or a cache). The integrated circuit design 310 may be executed so that it is elaborated (e.g., expanded) to include the instances of the module descriptions. For example, the integrated circuit design 310 may be elaborated to include instances 1 through N of module description 1, and instances 1 through M of module description 2. The module descriptions can be manipulated using functions of a general-purpose programming language (e.g., embedded in Scala). Interfaces to the module descriptions can be encoded in types associated with the general-purpose programming language.

An instance of a module description may be representative of hardware to be implemented in the integrated circuit (e.g., the processor core or the cache). For example, module description 1 may correspond to a processor core, and instances 1 through N of module description 1 may correspond to N instances of the processor core. For example, module description 2 may correspond to a cache, and instances 1 through M of module description 2 may correspond to M instances of the cache. Additionally, one or more instances may be configured to be in communication with one or more other instances. For example, the instances of module description 1 may be connected (e.g., wired) to the instances of module description 2, such via an internal system bus (e.g., internal to the integrated circuit design 310). In some implementations, the internal system bus could be a TileLink bus to be implemented in an ASIC or an SoC.

An instance of a module description may include inputs and/or outputs that are internal to the integrated circuit design 310 (e.g., internal inputs and/or outputs). An instance of a module description may also include inputs and/or outputs that are external to the integrated circuit design 310 (e.g., system level inputs and/or outputs).

The integrated circuit design 310 may be compiled by the compiler 340 (e.g., execute the transformations) to generate the RTL data structure 345. The RTL data structure 345 may encode logic descriptions associated with the instances of module descriptions implemented in the integrated circuit design 310. In some implementations, the compiler 340 may be a FIRRTL compiler that compiles the integrated circuit design 310 to generate the RTL data structure 345. In some implementations, the RTL data structure 345 may comprise Verilog.

When the integrated circuit design 310 is compiled, inputs and/or outputs that are external to the integrated circuit design 310 may be exposed to the simulator 350 in the RTL data structure 345, while inputs and/or outputs that are internal to the integrated circuit design 310 might not be exposed to the simulator 350. Accordingly, in some implementations, the control interface 320 may execute in the system 300 to receive one or more parameters indicating that one or more inputs and/or outputs that are internal to the integrated circuit design 310 should be exposed to the simulator 350. This may permit the simulator 350 to force signal values to, and/or monitor signal values at, one or more nodes associated with the one or more inputs and/or outputs.

For example, the control interface 320 may be an API executing in the system 300. The control interface 320 may receive the one or more parameters pointing to the inputs and/or outputs in the integrated circuit design 310. For example, the control interface 320 may receive a first parameter pointing to an input of instance 1 of module description 1, indicating that such input should be exposed to the simulator 350 (e.g., for injecting a signal value or logic on a node associated with the input). The input and the node may correspond to a same point in the design. For example, the input of instance 1 of module description 1 may be an input associated with the internal system bus in the integrated circuit design 310. The control interface 320 may also receive a second parameter pointing to an output of instance 1 of module description 1, indicating that such output should be exposed to the simulator 350 (e.g., for detecting a signal value or logic on a node associated with the output). The output and the node may correspond to a same point in the design. For example, the output of instance 1 of module description 1 may be an output associated with the internal system bus in the integrated circuit design 310.

In some implementations, a point in the integrated circuit design 310 may be an input and an output (e.g., bi-directional or I/O). The control interface 320 may receive a parameter indicating that the input and the output should be exposed to the simulator 350 (e.g., for injecting a signal value or logic and/or detecting a signal value or logic on a node associated with the input and the output).

The control interface 320 may execute in the system 300 to generate one or more compiler annotations 335 for the compiler 340. The annotations 335 may be based on the one or more parameters received by the control interface 320. The annotations 335 may be used to build and/or modify one or more transformations that are executed by the compiler 340, such as to configure cross module references, force statements, and/or binding logic with respect to one or more nodes in the RTL data structure 345 (e.g., associated with the inputs and/or outputs specified by the parameters). This may permit access to the one or more nodes by the simulator 350. This may also permit mapping the one or more nodes to force statements, as opposed to wires in the RTL data structure 345. In some implementations, the annotations 335 may comprise one or more strings in a serialized data format.

The compiler 340 may execute the one or more transformations, based on the annotations 335, to generate a configuration file 348 (e.g., instructions) that may be used by the simulator 350. The configuration file 348 may permit the simulator 350 to access the one or more nodes in the RTL data structure 345. For example, the configuration file 348 may include representations of cross module references, force statements, and/or binding logic that permit the simulator 350 to access the one or more nodes when simulating the RTL data structure 345. In some implementations, the configuration file 348 may comprise Verilog. Accordingly, driving logic may be configured in the annotations 335, based on the one or more parameters specifying internal input(s) and/or output(s) in the integrated circuit design 310, for the compiler 340 to produce driving logic for the simulator to use in connection with nodes in the RTL data structure 345 that are associated with the input(s) and/or output(s).

The simulator 350, which may be a simulator that natively supports force statements (such as Synopsys VCS), may use the configuration file 348 to access the one or more nodes when simulating the RTL data structure 345 (e.g., when executing test vectors). In other words, the configuration file may implement the cross module references, force statements, and/or binding logic for simulating the RTL data structure 345. For example, the simulator 350 may use the configuration file 348 to access a first node associated with an input, such as to inject a signal value or logic to the node (e.g., signal forcing). The simulator 350 may also use the configuration file 348 to access a second node associated with an output, such as to detect a signal value or logic on the node (e.g., signal monitoring). Accordingly, the simulator 450 may simulate the RTL data structure 345, using the configuration file 348, to verify (e.g., test) logic that is internal to the design as desired for functional verification (such as a logic description associated with an instance of module description 2, which might correspond to a cache). For example, the simulator 350 may simulate the RTL data structure 345, using the configuration file 348, to test logic associated with a cache that is internal to the design by forcing a signal value to a first node (e.g., associated with an input of the cache) and by monitoring a signal value on a second node (e.g., associated with an output of the cache).

FIG. 4 is a block diagram of another example of a system 400 for integrated circuit design verification with signal forcing. The system 400 may include an integrated circuit design 410, a control interface 420, and a compiler 440, like the integrated circuit design 310, the control interface 320, and the compiler 340, shown in FIG. 3, respectively. An integrated circuit generator may be used to generate the integrated circuit design 410. For example, the integrated circuit design service infrastructure 110 shown in FIG. 1 may be used to generate the integrated circuit design 410.

The control interface 420 may execute in the system 400 to receive one or more parameters indicating that certain inputs and/or outputs that are internal to the integrated circuit design 410 should be exposed to the simulator 450 (e.g., for signal forcing and/or signal monitoring by the simulator 450). For example, the control interface 420 may be an API executing in the system 400. The control interface 420 may receive the one or more parameters pointing to the inputs and/or outputs in the integrated circuit design 410. For example, the control interface 420 may receive a first parameter pointing to an input of instance 1 of module description 1 in the integrated circuit design 410, indicating that such input should be exposed to the simulator 450 (e.g., for injecting a signal value or logic on a node associated with the input). The input and the node may correspond to a same point in the design. For example, the input of instance 1 of module description 1 may be an input associated with the internal system bus in the integrated circuit design 410. The control interface 420 may also receive a second parameter pointing to an output of instance 1 of module description 1 in the integrated circuit design 410, indicating that such output should be exposed to the simulator 450 (e.g., for detecting a signal value or logic on a node associated with the output). The output and the node may correspond to a same point in the design. For example, the output of instance 1 of module description 1 may be an output associated with the internal system bus in the integrated circuit design 410.

The control interface 420 may execute in the system 400 to generate one or more compiler annotations 435 for the compiler 440. The annotations 435 may be based on the one or more parameters received by the control interface 420. The annotations 435 may be used to build and/or modify one or more transformations that are executed by the compiler 440, such as to configure cross module references, force statements, and/or binding logic with respect to one or more nodes in the RTL data structure 445 (e.g., associated with the inputs and/or outputs specified by the parameters). This may permit access to the one or more nodes by the simulator 450. This may also permit mapping the one or more nodes to force statements, as opposed to wires in the RTL data structure 445. In some implementations, the annotations 435 may comprise one or more strings in a serialized data format.

The compiler 440 may execute the one or more transformations, based on the annotations 435, to compile the integrated circuit design 410 to generate the RTL data structure 445. The RTL data structure 445, as produced by the compiler, may permit the simulator 450 to access the one or more nodes in the RTL data structure 445. For example, the RTL data structure 445 may include representations of cross module references, force statements, and/or binding logic that permit the simulator 450 to access the one or more nodes when simulating the RTL data structure 445. Accordingly, driving logic may be configured in the annotations 435, based on the one or more parameters specifying internal input(s) and/or output(s) in the integrated circuit design 410, for the compiler 440 to produce driving logic for the simulator to use in connection with nodes in the RTL data structure 445 that are associated with the input(s) and/or output(s).

The simulator 450, which may be a simulator that does not natively support force statements (such as Verilator), may then use the RTL data structure 445 to access the one or more nodes when simulating the RTL data structure 445 (e.g., when executing test vectors). In other words, the RTL data structure 445 that is simulated by the simulator 450 may already have the cross module references, force statements, and/or binding logic implemented. For example, the simulator 450 may use the RTL data structure 445 to access a first node associated with an input, such as to inject a signal value or logic to the node (e.g., signal forcing). The simulator 450 may also use the RTL data structure 445 to access a second node associated with an output, such as to detect a signal value or logic on the node (e.g., signal monitoring). Accordingly, the simulator 450 may simulate the RTL data structure 445 to verify (e.g., test) logic that is internal to the design as desired for functional verification (such as a logic description associated with an instance of module description 2, which might correspond to a cache). For example, the simulator 450 may simulate the RTL data structure 445 to test logic associated with a cache that is internal to the design by forcing a signal value to a first node (e.g., associated with an input of the cache) and by monitoring a signal value on a second node (e.g., associated with an output of the cache).

FIG. 5 is a block diagram of an example of a system 500 including an integrated circuit design with instances of module descriptions. The system 500 may include the integrated circuit design 510 and a control interface 520 like the integrated circuit design 310 and the control interface 320 shown in FIG. 3 and/or the integrated circuit design 410 and the control interface 420 shown in FIG. 4. An integrated circuit generator may be used to generate the integrated circuit design 510. For example, the integrated circuit design service infrastructure 110 shown in FIG. 1 may be used to generate the integrated circuit design 510.

The integrated circuit design 510 may be elaborated (e.g., expanded) to include one or more instances of one or more module descriptions, such as instances 515A and 515B of a first module description, and instance 517A of a second module description. For example, instances 515A and 515B may be instances of a module description corresponding to a processor core (e.g., processor core 1 and processor core 2). For example, instance 517A may be an instance of a module description corresponding to a cache (e.g., a level 3 (L3) cache shared by processor core 1 and processor core 2). The integrated circuit design 510 may be elaborated by executing the integrated circuit design 510. For example, the integrated circuit design 510 may be elaborated by executing Chisel. The integrated circuit design 510 may be encoded in IR data structure (e.g., a FIRRTL data structure).

The instances may include inputs and/or outputs that are internal to the integrated circuit design 510 (e.g., internal inputs and/or outputs). For example, instances 515A and 515B may include inputs and/or outputs to an internal system bus 560, such as via connections 570A and 570B, respectively. In some implementations, the internal system bus 560 could be a TileLink bus. Further, instance 517A may include inputs and/or outputs to the internal system bus 560, such as via connection 580A. The instances 515A and 515B and the instance 517A may be configured to communicate with one another via the internal system bus 560, such as for processing memory requests (e.g., reads and/or writes) between processor cores and cache. The instances may also include inputs and/or outputs that are external to the integrated circuit design 510 (e.g., system level inputs and/or outputs). For example, instance 517A may include inputs and/or outputs external to the integrated circuit design 510, such as via connections 590A. The instance 517A may be configured to communicate external to the integrated circuit design 510 via the connections 590A, such as for processing memory requests (e.g., reads and/or writes) through cache controller associated with a main memory (not shown).

The integrated circuit design 510 may be compiled by a compiler (e.g., the compiler 340 or the compiler 440) to generate an RTL data structure (e.g., the RTL data structure 345 or the RTL data structure 445). The RTL data structure may encode logic descriptions associated with instances in the integrated circuit design 510, such as instances 515A, 515B, and 517A. When the integrated circuit design 510 is compiled, inputs and/or outputs that are external to the integrated circuit design 510 (e.g., connections 590A) may be exposed to a simulator (e.g., the simulator 350 or the simulator 450). Inputs and/or outputs that are internal to the integrated circuit design 510 (e.g., connections 570A and 570B) might not be exposed to the simulator.

FIG. 6 is a block diagram of an example of a system 600 including an integrated circuit design 610 in which an input of an instance of a module description is selected for signal forcing. The system 600 may include the integrated circuit design 610 and a control interface 620 like the integrated circuit design 510 and the control interface 520 shown in FIG. 5. An integrated circuit generator may be used to generate the integrated circuit design 610. For example, the integrated circuit design service infrastructure 110 shown in FIG. 1 may be used to generate the integrated circuit design 610.

The integrated circuit design 610 may be elaborated (e.g., expanded) to include one or more instances of one or more module descriptions, such as instances 615A and 615B of a first module description, and instance 617A of a second module description. For example, instances 615A and 615B may be instances of a module description corresponding to a processor core (e.g., processor core 1 and processor core 2). For example, instance 617A may be an instance of a module description corresponding to a cache (e.g., an L3 cache shared by processor core 1 and processor core 2). The integrated circuit design 610 may be elaborated by executing the integrated circuit design 610. For example, the integrated circuit design 610 may be elaborated by executing Chisel. The integrated circuit design 610 may be encoded in IR data structure (e.g., a FIRRTL data structure).

The instances may include inputs and/or outputs that are internal to the integrated circuit design 610 (e.g., internal inputs and/or outputs). For example, instances 615A and 615B may include inputs and/or outputs to an internal system bus 660, such as via connections 670A and 670B, respectively. In some implementations, the internal system bus 660 could be a TileLink bus. Further, instance 617A may include inputs and/or outputs to the internal system bus 660, such as via connections 680A. For example, the instances 615A and 615B and the instance 617A may be configured to communicate with one another via the internal system bus 660, such as for processing memory requests (e.g., reads and/or writes) between processor cores and cache.

The instances may also include inputs and/or outputs that are external to the integrated circuit design 610 (e.g., system level inputs and/or outputs). For example, instance 517A may include inputs and/or outputs external to the integrated circuit design 610, such as via connection 690A. The instance 617A may be configured to communicate external to the integrated circuit design 610 via the connection 690A, such as for processing memory requests (e.g., reads and/or writes) through cache controller associated with a main memory (not shown).

The integrated circuit design 610 may be compiled by a compiler (e.g., the compiler 340 or the compiler 440) to generate an RTL data structure (e.g., the RTL data structure 345 or the RTL data structure 445). The RTL data structure may encode logic descriptions associated with instances in the integrated circuit design 610, such as instances 615A, 615B, and 617A. When the integrated circuit design 610 is compiled, inputs and/or outputs that are external to the integrated circuit design 610 (e.g., the connections 690A) may be exposed to a simulator (e.g., the simulator 350 or the simulator 450). Inputs and/or outputs that are internal to the integrated circuit design 610 (e.g., the connections 670A, 670B, and 680A) might not be exposed to the simulator.

Accordingly, in some implementations, the control interface 620 may execute in the system 600 to receive one or more parameters indicating that one or more inputs and/or outputs that are internal to the integrated circuit design 610 (e.g., the connections 670A, 670B, and/or 680A) should be exposed to the simulator. This may permit the simulator to force signal values to, and/or monitor signal values at, one or more nodes associated with the one or more inputs and/or outputs when simulating the RTL data structure. For example, instance 617A may correspond to an L3 cache comprising an error correction code (ECC) memory. The control interface 620 may receive a first parameter pointing to an input of instance 617A (e.g., via the connections 680A) and a second parameter pointing to an output of instance 617A (e.g., also via the connections 680A). The control interface 620 may execute to generate one or more compiler annotations (e.g., the annotations 335 or the annotations 435), based on the parameters, to build and/or modify one or more transformations for the compiler. In turn, the compiler may configure cross module references, force statements, and/or binding logic with respect to first and second nodes associated with the input and the output (e.g., in a configuration file and/or in the RTL data structure), respectively. The simulator may then simulate the RTL data structure using the cross module references, force statements, and/or binding logic to access the nodes. For example, the simulator may simulate the RTL data structure by injecting a signal value on the first node associated with the input (e.g., forcing a signal value, such as injecting a logic high (“1”) or a logic low (“0”) value) so as to induce an ECC error in the cache (e.g., flip a bit). The simulator may then monitor a signal value on the second node associated with the output (e.g., detecting a logic high (“1”) or a logic low (“0”) value) to determine whether the ECC memory properly detected the error and/or corrected the error.

In some implementations, the integrated circuit design 610 may implement a verification logic 632. For example, the verification logic 632 may be generated when the integrated circuit design 610 is elaborated. The verification logic 632 may include inputs and/or outputs that are external to the integrated circuit design 610 and therefore exposed to a simulator (e.g., system level inputs and/or outputs), such as the connections 695A. To permit the simulator to force signal values to, and/or monitor signal values at, one or more nodes associated with the one or more inputs and/or outputs that are internal to the integrated circuit design 610 (e.g., internal inputs and/or outputs), the verification logic 632 may be further connected to the one or more inputs and/or outputs that are internal to the integrated circuit design 610. For example, to permit the simulator to force signal values to an input and/or monitor signal values at an output of instance 617A, such as via the connections 680A, the verification logic 632 may be connected to the input and/or the output via the connections 680A. A simulator may then access nodes associated with the input and/or the output (e.g., the connections 680A) via the verification logic 632 and the connections 695A. For example, an API may be used to access the connections 690A and 695A.

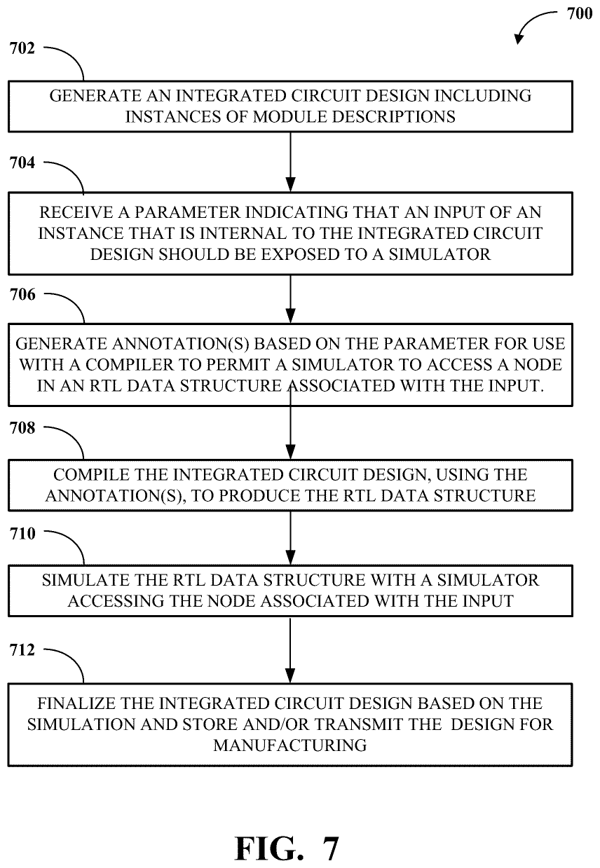

FIG. 7 is flow chart of a process 700 for integrated circuit design verification with signal forcing. The process 700 includes generating 702 an integrated circuit design including instances of module descriptions; receiving 704 a parameter indicating that an input of an instance should be exposed to a simulator; generating 706 annotation(s) based on the parameters; compiling 708 the integrated circuit design, using the annotations, to produce an RTL data structure; simulating 710 the RTL data structure; and storing and/or transmitting 712 the integrated circuit design. For example, the process 700 may be implemented using the system 100 shown in FIG. 1, the system 200 shown in FIG. 2, the system 300 shown in FIG. 3, the system 400 shown in FIG. 4, the system 500 shown in FIG. 5, and/or the system 600 shown in FIG. 6.

The process 700 may include generating 702 an integrated circuit design (e.g., the integrated circuit design 410) including instances of module descriptions. For example, the integrated circuit design service infrastructure 110 shown in FIG. 1 may be used to generate the integrated circuit design. The generator may use an HDL embedded in a general-purpose programming language (e.g., Scala) that supports object-oriented programming and/or functional programming. For example, Chisel may be used to generate the integrated circuit design. The integrated circuit design may be encoded in an IR data structure (e.g., a FIRRTL data structure). The instances of module descriptions may be representative of hardware to be implemented in the integrated circuit design (e.g., processors cores, caches, and the like). The instances of module descriptions may include input(s) and/or output(s).

The process 700 may also include receiving 704 a parameter indicating that an input of an instance that internal to the integrated circuit design should be exposed to a simulator (e.g., the simulator 450). For example, an instance of a module description may include inputs and/or outputs that are internal to the integrated circuit design (e.g., internal inputs and/or outputs), and/or inputs and/or outputs that are external to the integrated circuit design (e.g., system level inputs and/or outputs). When the integrated circuit design is compiled to produce an RTL data structure (e.g., the RTL data structure 445), inputs and/or outputs that are external to the integrated circuit design may be exposed to the simulator by the RTL data structure, while inputs and/or outputs that are internal to the integrated circuit design might not be exposed to the simulator by the RTL data structure. Accordingly, in some implementations, a control interface (e.g., the control interface 420) may execute to receive a parameter indicating that an input that is internal to the integrated circuit design should be exposed to a simulator. In some implementations, the control interface may be an API executing in the system. The control interface may receive a parameter pointing to the input. In some implementations, the input may be associated with an input and an output (e.g., and I/O). In some implementations, the control interface may receive multiple parameters pointing to multiple inputs and/or outputs.

The process 700 may also include generating 706 one or more compiler annotation(s) based on the parameters for use with a compiler (e.g., the compiler 440). The one or more annotations may permit the simulator to access a node in the RTL data structure that is associated with the input. For example, the control interface may further execute in the system to generate the one or more annotations for the compiler. The one or more annotations may be based on the parameter. The one or more annotations may be used to build and/or modify one or more transformations that are executed by the compiler, such as to configure cross module references, force statements, and/or binding logic with respect to a node in the RTL data structure (e.g., associated with the input specified by the parameter). This may permit access to the one or more nodes by the simulator (e.g., the simulator 450). In some implementations, the one or more annotations may comprise one or more strings in a serialized data format.

The process 700 may also include compiling 708 the integrated circuit design using the one or more annotations. The compiler may compile the integrated circuit design (e.g., execute the transformations, based on the annotations) to produce the RTL data structure (e.g., the RTL data structure 445). The RTL data structure, as produced by the compiler, may permit the simulator to access the node (e.g., the node associated with the input that is internal to the integrated circuit design) in the RTL data structure. For example, the RTL data structure may include representations of cross module references, force statements, and/or binding logic that permit the simulator to access the node when simulating the RTL data structure. In some implementations, the compiler may be a FIRRTL compiler that compiles the integrated circuit design (e.g., in FIRRTL) to generate the RTL data structure. In some implementations, the compiler may compile the integrated circuit design to generate the RTL data structure comprising Verilog.

The process 700 may also include simulating 710 the RTL data structure with a simulator (e.g., the simulator 450) accessing the node (e.g., the node associated with the input that is internal to the integrated circuit design). The simulator may access the node to test a logic description associated with another instance of the integrated circuit design. For example, a simulator (such as Verilator), which might not natively support force statements, may use the RTL data structure to access the node when simulating the RTL data structure. In other words, the RTL data structure that is simulated by the simulator may already have the cross module references, force statements, and/or binding logic implemented. The simulator may simulate the RTL data structure to verify (e.g., test) logic that is internal to the design as desired for functional verification (such as a logic description associated with an instance of a module description).

The process 700 may also include storing and/or transmitting 712 the integrated circuit design. The integrated circuit design may be stored for use in subsequent steps, such as synthesis, placement and routing, implementation of clock trees, and/or simulation analysis. Additionally, the integrated circuit design may be transmitted for manufacturing of an integrated circuit, such as a SoC.

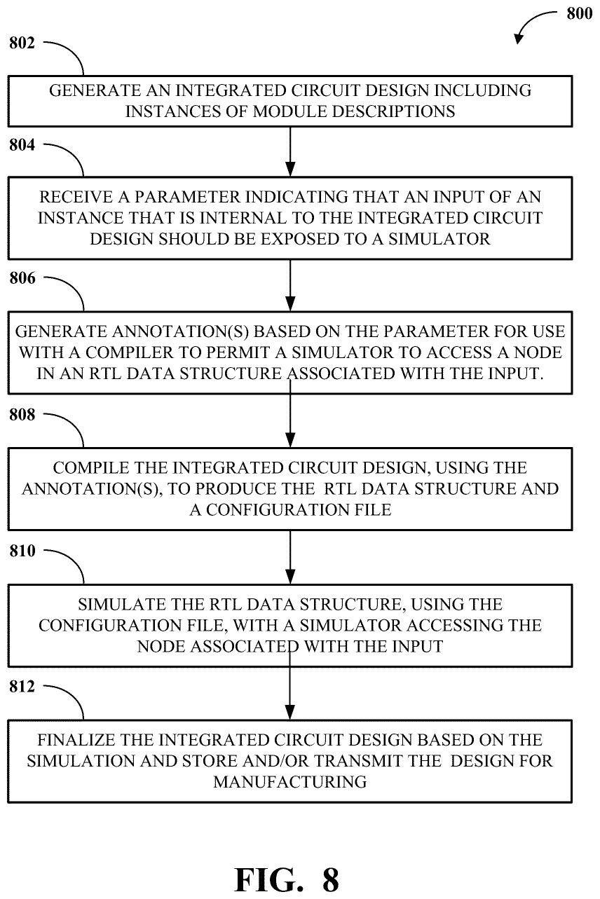

FIG. 8 is flow chart of a process 800 for integrated circuit design verification with signal forcing. The process 800 includes generating 802 an integrated circuit design including instances of module descriptions; receiving 804 a parameter indicating that an input of an instance should be exposed to a simulator; generating 806 annotation(s) based on the parameters; compiling 808 the integrated circuit design, using the annotation(s), to produce an RTL data structure and instructions to permit a simulator to access a node in the RTL data structure that is associated with the input; simulating 810 the RTL data structure using the instructions; and storing and/or transmitting 812 the integrated circuit design. For example, the process 800 may be implemented using the system 100 shown in FIG. 1, the system 200 shown in FIG. 2, the system 300 shown in FIG. 3, the system 400 shown in FIG. 4, the system 500 shown in FIG. 5, and/or the system 600 shown in FIG. 6.

The process 800 may include generating 802 an integrated circuit design (e.g., the integrated circuit design 310) including instances of module descriptions. For example, the integrated circuit design service infrastructure 110 shown in FIG. 1 may be used to generate the integrated circuit design. The generator may use an HDL embedded in a general-purpose programming language (e.g., Scala) that supports object-oriented programming and/or functional programming. For example, Chisel may be used to generate the integrated circuit design. The integrated circuit design may be encoded in an IR data structure (e.g., a FIRRTL data structure). The instances of module descriptions may be representative of hardware to be implemented in the integrated circuit design (e.g., processors cores, caches, and the like). The instances of module descriptions may include input(s) and/or output(s).

The process 800 may also include receiving 804 a parameter indicating that an input of an instance should be exposed to a simulator (e.g., the simulator 350). For example, an instance of a module description may include inputs and/or outputs that are internal to the integrated circuit design (e.g., internal inputs and/or outputs), and/or inputs and/or outputs that are external to the integrated circuit design (e.g., system level inputs and/or outputs). When the integrated circuit design is compiled to produce an RTL data structure (e.g., the RTL data structure 345), inputs and/or outputs that are external to the integrated circuit design may be exposed to the simulator by the RTL data structure, while inputs and/or outputs that are internal to the integrated circuit design might not be exposed to the simulator by the RTL data structure. Accordingly, in some implementations, a control interface (e.g., the control interface 320) may execute to receive a parameter indicating that an input that is internal to the integrated circuit design should be exposed to a simulator. In some implementations, the control interface may be an API executing in the system. The control interface may receive a parameter pointing to the input. In some implementations, the input may be associated with an input and an output (e.g., and I/O). In some implementations, the control interface may receive multiple parameters pointing to multiple inputs and/or outputs.

The process 800 may also include generating 806 one or more compiler annotation(s) based on the parameter for use with a compiler (e.g., the compiler 340). The one or more annotations may permit the simulator to access a node in the RTL data structure that is associated with the input. For example, the control interface may further execute in the system to generate the one or more compiler annotations for the compiler. The one or more annotations may be based on the parameter. The one or more annotations may be used to build and/or modify one or more transformations that are executed by the compiler, such as to configure cross module references, force statements, and/or binding logic with respect to a node in the RTL data structure (e.g., associated with the input specified by the parameter). This may permit access to the node by the simulator (e.g., the simulator 350). In some implementations, the one or more annotations may comprise one or more strings in a serialized data format.

The process 800 may also include compiling 808 the integrated circuit design using the one or more annotations. The compiler may compile the integrated circuit design (e.g., execute the transformations) to produce the RTL data structure (e.g., the RTL data structure 345). In some implementations, the compiler may be a FIRRTL compiler that compiles the integrated circuit design (e.g., in FIRRTL) to produce the RTL data structure. In some implementations, the compiler may compile the integrated circuit design to generate the RTL data structure comprising Verilog. The compiler may further execute the one or more transformations, based on the one or more annotations, to generate a configuration file (e.g., the configuration file) for the RTL data structure. The configuration file may permit the simulator to access the node (e.g., the node associated with the input that is internal to the integrated circuit design) in the RTL data structure. For example, the configuration file may include representations of cross module references, force statements, and/or binding logic that the simulator may use to access the node when simulating the RTL data structure. In some implementations, the configuration file may comprise Verilog.

The process 800 may also include simulating 810 the RTL data structure, using the configuration file, with a simulator (e.g., the simulator 350) accessing the node (e.g., the node associated with the input that is internal to the integrated circuit design). The simulator may access the node to test a logic description associated with another instance of the integrated circuit design. For example, a simulator (such as Synopsys VCS), which may natively support force statements, may use the configuration file to access the node when simulating the RTL data structure. In other words, the configuration file may implement the cross module references, force statements, and/or binding logic for simulating the RTL data structure. The simulator may simulate the RTL data structure, using the configuration file, to verify (e.g., test) logic that is internal to the design as desired for functional verification (such as a logic description associated with an instance of module description).

The process 800 may also include storing and/or transmitting 812 the integrated circuit design. The integrated circuit design may be stored for use in subsequent steps, such as synthesis, placement and routing, implementation of clock trees, and/or simulation analysis. Additionally, the integrated circuit design may be transmitted for manufacturing of an integrated circuit, such as a SoC.

In a first aspect, the subject matter described in this specification can be embodied in a method that includes: generating an integrated circuit design for an integrated circuit, wherein the integrated circuit design includes an instance of a module description that describes a functional operation of a module, wherein the instance includes an input that is internal to the integrated circuit design, and wherein the integrated circuit design is encoded in an intermediate representation (IR) data structure; receiving a parameter indicating that the input should be exposed to a simulator; compiling the IR data structure to produce a register-transfer level (RTL) data structure, wherein the RTL data structure encodes a logic description associated with the instance; and using the parameter to permit a simulator to access a node in the RTL data structure that is associated with the input. In some implementations, the method may include generating a configuration file to permit the simulator to access the node in the RTL data structure when simulating the RTL data structure. In some implementations, the method may include configuring the RTL data structure to permit the simulator to access the node in the RTL data structure when simulating the RTL data structure. In some implementations, the method may include simulating the RTL data structure, wherein the simulator forces a signal value to the node. In some implementations, the instance includes an output that is internal to the integrated circuit design, the parameter is a first parameter, and the node is a first node, and the method may include receiving a second parameter indicating that the output should be exposed to the simulator, wherein the second parameter is used to permit the simulator to access a second node in the RTL data structure that is associated with the output. In some implementations, the node is further associated with an output. In some implementations, the method may include the IR data structure is a FIRRTL data structure, and the RTL data structure comprises Verilog. In some implementations, the instance corresponds to an ECC memory, the node is a first node, and the method may include simulating the RTL data structure, wherein the simulator has access to the first node associated with the input that is internal to the integrated circuit design and has access to a second node that is external to the integrated circuit design, and wherein the simulator forces a signal value to the first node to induce an ECC error. In some implementations, the input is part of a system bus that is internal to the integrated circuit design. In some implementations, the module description describes a functional operation of at least one of a processor core or a cache. In some implementations, the input and the node correspond to a same point in the integrated circuit design.

In a second aspect, the subject matter described in this specification can be embodied in an apparatus that includes: a memory; and a processor configured to execute instructions stored in the memory to: generate an integrated circuit design for an integrated circuit, wherein the integrated circuit design includes an instance of a module description that describes a functional operation of a module, wherein the instance includes an input that is internal to the integrated circuit design, and wherein the integrated circuit design is encoded in an IR data structure; receive a parameter indicating that the input should be exposed to a simulator; compile the IR data structure to produce an RTL data structure, wherein the RTL data structure encodes a logic description associated with the instance; and use the parameter to permit a simulator to access a node in the RTL data structure that is associated with the input. In some implementations, the instructions include instructions to generate a configuration file to permit the simulator to access the node in the RTL data structure when simulating the RTL data structure. In some implementations, the instructions include instructions to configure the RTL data structure to permit the simulator to access the node in the RTL data structure when simulating the RTL data structure. In some implementations, the instructions include instructions to simulate the RTL data structure, wherein the simulator forces a signal value to the node. In some implementations, the instance includes an output that is internal to the integrated circuit design, the parameter is a first parameter, the node is a first node, and the instructions include instructions to receive a second parameter indicating that the output should be exposed to the simulator, wherein the second parameter is used to permit the simulator to access a second node in the RTL data structure that is associated with the output.

In a third aspect, the subject matter described in this specification can be embodied in a non-transitory computer-readable storage medium that includes instructions that, when executed by a processor, causes the processor to: generate an integrated circuit design for an integrated circuit, wherein the integrated circuit design includes an instance of a module description that describes a functional operation of a module, wherein the instance includes an input that is internal to the integrated circuit design, and wherein the integrated circuit design is encoded in an IR data structure; receive a parameter indicating that the input should be exposed to a simulator; compile the IR data structure to produce an RTL data structure, wherein the RTL data structure encodes a logic description associated with the instance; and use the parameter to permit a simulator to access a node in the RTL data structure that is associated with the input. In some implementations, the instructions, when executed by the processor, further cause the processor to generate a configuration file to permit the simulator to access the node in the RTL data structure when simulating the RTL data structure. In some implementations, the instructions, when executed by the processor, further cause the processor to configure the RTL data structure to permit the simulator to access the node in the RTL data structure when simulating the RTL data structure. In some implementations, the instructions, when executed by the processor, further cause the processor to simulate the RTL data structure, wherein the simulator forces a signal value to the node.

While the disclosure has been described in connection with certain embodiments, it is to be understood that the disclosure is not to be limited to the disclosed embodiments but, on the contrary, is intended to cover various modifications and equivalent arrangements included within the scope of the appended claims, which scope is to be accorded the broadest interpretation so as to encompass all such modifications and equivalent structures.

What is claimed is:

1. A method comprising:
generating an integrated circuit design for an integrated circuit, wherein the integrated circuit design includes an instance of a module description that describes a functional operation of a module, wherein the instance includes an input that is internal to the integrated circuit design, and wherein the integrated circuit design is encoded in an intermediate representation (IR) data structure;
receiving a parameter indicating that the input should be exposed to a simulator;
compiling the IR data structure to produce a register-transfer level (RTL) data structure, wherein the RTL data structure encodes a logic description associated with the instance such that the input is exposable to the simulator; and
using the parameter to permit the simulator to access a node in the RTL data structure that is associated with the input.

2. The method of claim 1, further comprising:
generating a configuration file to permit the simulator to access the node in the RTL data structure when simulating the RTL data structure.

3. The method of claim 1, further comprising:
configuring the RTL data structure to permit the simulator to access the node in the RTL data structure when simulating the RTL data structure.

4. The method of claim 1, further comprising:
simulating the RTL data structure, wherein the simulator forces a signal value to the node.

5. The method of claim 1, wherein the instance includes an output that is internal to the integrated circuit design, wherein the parameter is a first parameter, and wherein the node is a first node, and further comprising:
receiving a second parameter indicating that the output should be exposed to the simulator, wherein the second parameter is used to permit the simulator to access a second node in the RTL data structure that is associated with the output.

6. The method of claim 1, wherein the node is further associated with an output.

7. The method of claim 1, wherein the IR data structure is a flexible intermediate representation for register-transfer level (FIRRTL) data structure, and wherein the RTL data structure comprises Verilog.

8. The method of claim 1, wherein the instance corresponds to an error correction code (ECC) memory, and wherein the node is a first node, and further comprising:
simulating the RTL data structure, wherein the simulator has access to the first node associated with the input that is internal to the integrated circuit design and has access to a second node that is external to the integrated circuit design, and wherein the simulator forces a signal value to the first node to induce an ECC error.

9. The method of claim 1, wherein the input is part of a system bus that is internal to the integrated circuit design.

10. The method of claim 1, wherein the module description describes a functional operation of at least one of a processor core or a cache.

11. The method of claim 1, wherein the input and the node correspond to a same point in the integrated circuit design.

12. An apparatus, comprising:
a memory; and
a processor configured to execute instructions stored in the memory to:
generate an integrated circuit design for an integrated circuit, wherein the integrated circuit design includes an instance of a module description that describes a functional operation of a module, wherein the instance includes an input that is internal to the integrated circuit design, and wherein the integrated circuit design is encoded in an IR data structure;
receive a parameter indicating that the input should be exposed to a simulator;
compile the IR data structure to produce an RTL data structure, wherein the RTL data structure encodes a logic description associated with the instance such that the input is exposable to the simulator; and
use the parameter to permit the simulator to access a node in the RTL data structure that is associated with the input.

13. The apparatus of claim 12, wherein the instructions include instructions to:
generate a configuration file to permit the simulator to access the node in the RTL data structure when simulating the RTL data structure.

14. The apparatus of claim 12, wherein the instructions include instructions to:
configure the RTL data structure to permit the simulator to access the node in the RTL data structure when simulating the RTL data structure.

15. The apparatus of claim 12, wherein the instructions include instructions to:
simulate the RTL data structure, wherein the simulator forces a signal value to the node.

16. The apparatus of claim 12, wherein the instance includes an output that is internal to the integrated circuit design, wherein the parameter is a first parameter, wherein the node is a first node, and wherein the instructions include instructions to:
receive a second parameter indicating that the output should be exposed to the simulator, wherein the second parameter is used to permit the simulator to access a second node in the RTL data structure that is associated with the output.

17. A non-transitory computer-readable storage medium that includes instructions that, when executed by a processor, causes the processor to:
generate an integrated circuit design for an integrated circuit, wherein the integrated circuit design includes an instance of a module description that describes a functional operation of a module, wherein the instance includes an input that is internal to the integrated circuit design, and wherein the integrated circuit design is encoded in an IR data structure;
receive a parameter indicating that the input should be exposed to a simulator;
compile the IR data structure to produce an RTL data structure, wherein the RTL data structure encodes a logic description associated with the instance such that the input is exposable to the simulator; and
use the parameter to permit the simulator to access a node in the RTL data structure that is associated with the input.

18. The non-transitory computer-readable storage medium of claim 17, wherein the instructions, when executed by the processor, further cause the processor to:
generate a configuration file to permit the simulator to access the node in the RTL data structure when simulating the RTL data structure.

19. The non-transitory computer-readable storage medium of claim 17, wherein the instructions, when executed by the processor, further cause the processor to:
configure the RTL data structure to permit the simulator to access the node in the RTL data structure when simulating the RTL data structure.

20. The non-transitory computer-readable storage medium of claim 17, wherein the instructions, when executed by the processor, further cause the processor to:
simulate the RTL data structure, wherein the simulator forces a signal value to the node.
